(19) United States
(12) Patent Application Publication
(10) Pub. No.: US 2003/0221610 A1
(43) Pub. Date: Dec. 4, 2003

(54) Process for growing calcium fluoride single crystals

(76) Inventors: Evgeny A. Garibin, St. Petersburg (RU); Aleksey A. Demidenko, St. Petersburg (RU); Igor A. Mironov, St. Petersburg (RU); Gury T. Petrovsky, St. Petersburg (RU); Vladimir M. Reyterov, St. Petersburg (RU); Aleksandr N. Sinev, St. Petersburg (RU)

Correspondence Address: CORNING INCORPORATED, SP-TI-3-1, CORNING, NY, 14831

(21) Appl. No.: 10/424,013

(22) Filed: Apr. 25, 2003

(30) Foreign Application Priority Data
May 31, 2002 (RU) 2002115062

(51) Int. Cl. C30B 9/00; C30B 11/00; C30B 17/00; C30B 21/02; C30B 28/06

(52) U.S. Cl. 117/82; 117/81; 117/83

(57) ABSTRACT

The present invention is directed to the technical field of the manufacture of calcium fluoride single crystals by growing from a melt by the directed crystallization and by using a seed crystal, such crystals having high optical homogeneity and small birefringence. The method includes crystallization from a melt and an annealing of crystals with the subsequent cooling in the vacuum furnace by continuous transfer of the crucible containing a melt from a melt zone into the annealing zone at independent regulation of modes of both zones in which the cooling of crystals in the range 1100-700° C. is carried out with a rate of 1.3-2.0° C./hr, a constant axial temperature drop with a gradient 20-50° C./m at is provided in the absence (or minimum) radial gradient, and this is provided by moving downwards a water-cooled rod moving at a speed of 0.8-1.4 of the speed of the crystal movement, the water-cooled rod being arranged towards a crucible bottom at a distance equal to 0.3-0.4 from a height of a heater of the annealing zone.

### RELATED APPLICATION

This application claims the benefit of Russian Patent Application Number 2002115062, filed May 31, 2002, which is incorporated herein by reference in its entirety.

### FIELD OF THE INVENTION

The present invention relates to the technical field of manufacture of calcium fluoride single crystals by growing from a melt by a method of cooling using a temperature gradient and a seed crystal.

### BACKGROUND OF THE INVENTION

The industrial manufacturing of optical calcium fluoride [also know as “calcium fluorite”] crystals is based on direct crystallization by the Bridgeman-Stockbarger method, the basis of which is the moving of crucible containing a melt of calcium fluoride through a thermal field with specified gradient in high vacuum. This method allows one to grow the large-sized single crystals of cylindrical shape of a given diameter by the use of the appropriate container or crucible. In this process there are radial and axial thermal gradients involved in growing the cylindrical crystal. These axial and radial gradients create residual stresses that differ both in size and in sign. Residual stresses are the reason of optical homogeneity deterioration, which manifests as areas with anomolous birefringence. As a result, it is necessary to choose a strict temperature-time regime for crystal growth in order to reduce the residual stress, and especially one must give attention to annealing process.

A process for growing of calcium fluoride crystals has been described in the book entitled “Opticheskiy flyuorit” (Optical Fluorite) by N. P. Yushkin et al., published by Nauka in Moscow in 1983 (see pp. 83 and 84). This process includes the prior preparation, in which the apparatus and the crucible are first cleaned with compressed air, and then the crucible is filled with fluorite fragments, and the installation, including the filled crucible, is pumped out to a pressure not less than 1×10⁻⁴ mm Hg. The crucible is then heated to 1500° C. at a rate of 5° C. /min during 5 hours. The material is kept at this holding temperature until it is completely melted and the melt is fully homogeneous. The time required for this depends on the size of the crucible and can be up to 20 hours. The crucible containing the melt is then automatically lowered at speed of 2-20 mm/hour at a constant crystallization temperature of 1450° C. When crystallization has stopped, the temperature in upper zone of the furnace is reduced to a value of between 800 and 1150° C., depending on the size of the crystals. The crucible containing the crystals is then raised again to its initial position in the upper zone and kept there for 5-10 hours. The temperature is then reduced to 250-150° C. at a rate of 3-25° C. /hour. The heating is finally stopped, and the crystals are allowed to cool down naturally over the rest of the temperature range.

The disadvantage of this process is that the crystal preparation is discontinuous, and the crystals have to be heated twice in the upper zone. This can lead to stresses in the resulting single crystals and to the formation of sites in them with different orientation (blocks or “mosaic”).

Two isothermal regions, with a temperature drop between them, are generally used when growing crystals in a downward moving of crucible. This makes it possible to anneal the crystals right after growing them, without subjecting them to the high thermal stresses that occur when there is an extremely great temperature drop. The furnace used in this instance should have two temperature zones, with a minimal heat exchange between them. For this purpose, a thermal insulator and a shielding screen separate these zones, and the temperature in the two zones is regulated independently from each other by a special heaters system.

Such method is described in a book by R. Lodiz and R. Parker, entitled “Rost kristallov” (Growth of Crystals), translated from English into Russian, edited by A. A. Chernov and published by Mir in Moscow in 1974, p. 181. In the process described in this book, the melt is cooled at the rate of at least 7° C./cm, and the crucible moved with a speed of 1-5 mm/hour. The above method is the closest prior art to the invention as to the technical essence. However, the details for the specific conditions of the processes for growing single crystals, and the qualitative characteristics of the grown single crystals are not provided by the above prior art. Careful special selection of modes at all stages of crystal growth and annealing is necessary for obtaining of qualitative or high quality fluoride crystals suitable for the purpose of manufacturing from them optical elements with required optical characteristics.

The purpose of the present invention is directed to the growing of calcium fluoride single crystals which have a high optical homogeneity (Δn=1×10⁻⁶) and a low birefringence (δ=0.5-1.0 nm/cm).

We suggest a method of growing calcium fluoride monocrystals which utilizes melting and annealing of crystals and cooling in a vacuum

The invention provides a method of growing calcium fluoride monocrystals which utilizes melting and annealing of crystals and cooling in a vacuum furnace via continued movement of the crucible from the melting zone to the annealing zone while independently regulating the heat of these zones, wherein the difference from the prior art is,

the cooling of the crystals in the temperature an interval 1100-700° C. is carried out at a rate of 1.3-2.0° C./hr,

the constant axial temperature drop with a gradient 20-50° C./m at absence or the minimal radial gradient (which is provided by moving a water-cooled rod down with the speed 0.8-1.4 from speed of moving crucible with crystals from a melt zone into a annealing zone) is kept in the annealing zone,

the water-cooled rod is arranged towards a crucible bottom on the distance equal to 0.3-0.4 from a height of a heater of the annealing zone.

The above technological mode was determined in an experimental way. The crystal cooling in the temperature interval 1100-700° C. at a rate of 1.3-2.0° C./hr was controlled by regulation of the heater's power in both zones of the growth installation [furnace]. It is experimentally shown that exactly in this temperature interval the slower rate of cooling is necessary so that the induced internal stresses both during growth of a crystal and at its annealing are eliminated. The radial gradient which especially influences the crystal birefringence value is minimized or absolutely removed by the use of the above mode of speed movement of the growing crystal moving from the melt zone into the annealing zone and the appropriate arrangement and movement of a water-cooled rod.

### BRIEF DESCRIPTION OF THE DRAWING

FIG. 1 illustrates the vacuum furnace and associated equipment used in practicing the invention.

### DETAILED DESCRIPTION OF THE INVENTION

The invention is directed to a method of growing calcium fluoride monocrystals which utilizes melting and annealing of crystals and cooling in a vacuum furnace via continued movement of the crucible from the melting zone to the annealing zone while independently regulating the heat of these zones. In particular, the present invention illustrates the following features that are not present in the prior art is:

1. The cooling of the crystals in the temperature an interval 1100-700° C. is carried out at a rate of 1.3-2.0° C./hr;

2. The constant axial temperature drop with a gradient 20-50° C./m at absence or the minimal radial gradient (which is provided by moving a water-cooled rod down with the speed 0,8-1,4 from speed of moving crucible with crystals from a melt zone into a annealing zone) is kept in the annealing zone,

3. The water-cooled rod is arranged towards a crucible bottom on the distance equal to 0.3-0.4 from a height of a heater of the annealing zone.

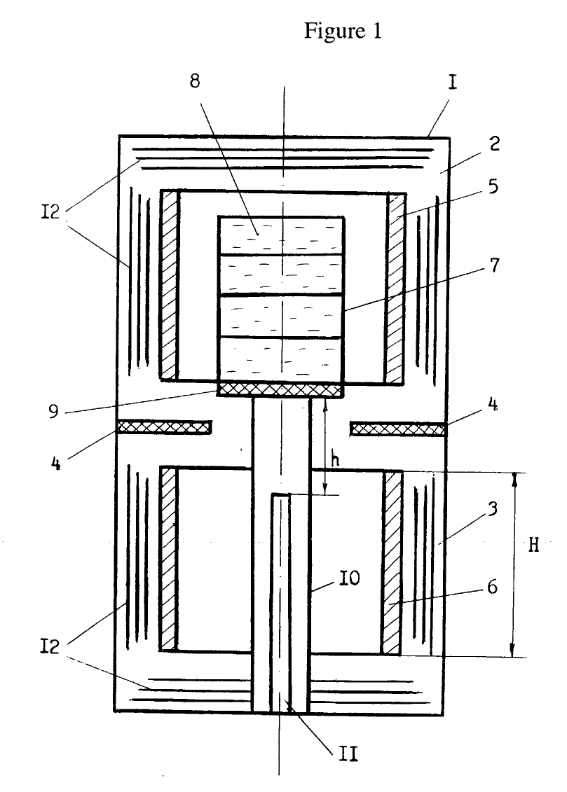

FIG. 1 is a schematic illustrating the installation used for growing crystals according to the invention. In FIG. 1 furnace body 1 has two zones. The top zone is a melt zone 2 and the bottom zone is an annealing zone 3, and these zones are divided with a diaphragm [“baffle”] 4. Each zone has the heaters 5 and 6, respectively. Inside the installation there is the crucible 7 with raw material 8 (fluorite flake) in it. The crucible is arranged on a plate 9 with a first rod 10 attached thereto. A second water-cooled rod 11 is located inside the first rod 10. Element 12 is the screen of the furnace. Diaphragm 4 in zone of partition between the two basic technological zones 2 and 3 creates a “crystallization zone” in this area.

Actual realization of the method was carried out as follows. A fluoride charge, in form of small pieces of fluoride crystals, is filled into cleaned graphite crucible consisting of 4 bowls. A crucible 7 is put in a growth installation on a rod 10, connected with programmed [controlled] management. The top zone 2 and the annealing zone 3 are provided with separate regulation of the temperature modes by means of the use of heaters 5 and 6. The installation is pumped out to pressure not less than 1×10⁻⁶ mm Hg, and then the temperature raised to 1500° C. with the help of heater power 5 regulation in the top zone 2, and the temperature of the annealing zone 3 is raised to 1250° C. by the regulation of heater power 6. In the beginning of process the crucible is located in the top part of installation and is held at the maximum temperature of 1500° C. for 30 hours until the melt is homogeneous and is free of inclusions and bubbles. Then, the crucible 7 with the melt 8 is begun to descend with at a speed of 0.7-2 mm/hr. When the crucible has passed the diaphragm 4 level where the crystallization of substance begins, its movement into the annealing zone 3 is done at a speed 2-5 mm/hr. Thus, the temperature of the top and bottom heaters 5 and 6 change in such a manner that cooling of the substance in the temperature range 1500-1250° C. is carried out at a rate 7-5° C./hr, in the temperature range 1250-1100° C. at a rate of 5-2° C./hr, in the temperature range 1100-700° C. at a rate of 1.3-2° C./hr, in the temperature range 700-400° C. at a rate of 3.5-7.0° C./hr, and in the temperature range 400-100° C. at a rate of 10-15° C./hr.

Two concrete examples of temperature change of the top heater 5 and bottom heater 6 for maintenance of the above-described mode of crystal cooling are shown in the tables:

| Example 1 | | | | Example 2 | | | |
|---|---|---|---|---|---|---|---|
| Top heater | | Bottom heater | | Top heater | | Bottom heater | |
| T, ° C. | ΔT/Δt | T, ° C. | ΔT/Δt | T, ° C. | ΔT/Δt | T, ° C. | ΔT/Δt |
| 1500 | 7.0 | 1250 | 3.95 | 1500 | 13.3 | 1250 | 4.99 |
| 1234 | 2.16 | 1100 | 1.61 | 1300 | 13.3 | 1175 | 499 |
| 1100 | 1.55 | 1000 | 1.30 | 1100 | 1.5 | 1100 | 1.5 |
| 960 | 1.55 | 883 | 1.30 | 940 | 1.5 | 940 | 1.5 |
| 820 | 1.50 | 766 | 1.30 | 800 | 1.5 | 800 | L30 |
| 790 | 3.00 | 740 | 2.00 | 740 | 2.0 | 740 | 2.00 |
| 730 | 4.25 | 700 | 3.75 | 700 | 3.75 | 700 | 3.75 |
| 560 | 5.83 | 550 | 6.25 | 550 | 6.25 | 550 | 6.25 |
| 420 | 10.97 | 400 | 10.42 | 400 | 10.42 | 400 | 10.42 |
| 25 | | 25 | | 25 | | 25 | |

In this example the water-cooled rod 11 is put a distance of 240 mm from the bottom of crucible 7, that makes 0.3 the height H of a heater 6 of the annealing zone 3 which in this case is equal 800 mm (see drawings). The water-cooled rod 11 will move with the same speed as the movement of the crucible 7. Taking into account the independent moving of water-cooled rod, irrespective of the crucible, the deflection of its speed of moving should not exceed 0.8-1.4 of the crucible's speed.

The minimal axial gradient in the temperature interval 1100-700° C. is maintained at level 20-50° C./m by means of the above-stated conditions provide.

Four calcium fluoride crystals with a diameter of 300 mm and a height of 80 mm have been grown for one working cycle. The crystals obtained using the above described method have a high optical homogeneity (Δn=1.10-6) and a small birefringence (δ=0.5-1.0 nm/cm). The foregoing examples of specific compositions, processes, articles and/or apparatus employed in the practice of the present invention are, of course, intended to be illustrative rather than limiting, and it will be apparent the numerous variations and modification of these specific embodiments may be practiced within the scope of the specification, drawing and appended claims.

1. A process for growing of calcium fluoride single crystals, which includes crystallization from a melt and an annealing of the crystals with subsequent cooling in a vacuum furnace by continuous transfer of crucible containing a melt from a melt zone into an annealing zone at independent regulation of modes of both zones, the process comprising
the cooling of the crystals a temperature range 1100-700° C. is carried out with a rate 1.3-2.0° C./hr. and with a constant axial temperature drop with a gradient 20-50° C./m in the absence or minimal presence of a radial gradient, the cooling being provided by moving downwards a water-cooled rod with a speed in the range of 0.8-1.4 of the speed of the crystal movement, and the water-cooled rod being arranged towards a crucible bottom at a distance equal to 0.3-0.4 the from a height of a heater of the annealing zone.

2. A process for growing calcium fluoride single crystals, the process comprising:
(a) placing a calcium fluoride charge in a crucible;
(b) placing the crucible in a furnace having a melt zone and an annealing zone, said zones being separated by a diaphragm;
reducing the pressure in the furnace to not less than 1×10⁻⁶ mm Hg
(c) heating the charge in the crucible to a temperature of 1500° C. and holding the charge in the melt zone at the temperature for a time sufficient for the melt to become homogeneous and to free of inclusions and bubbles; and
(d) lowering the melt of step (c) from the melt zone into the annealing zone that is at a temperature of 1250° C. at a speed of 0.7-2.0 mm/hour until the crucible has passed the diaphragm; and
(e) lowering the temperature of the melt in a controlled manner to ambient temperature.

3. The process according to claim 2, wherein the cooling of the melt in the temperature range of 1100-700° C. is done at a rate of 1.3-2.0° C./hour.

4. The method according to claim 2, wherein rate of cooling of the melt is:
(a) from 1500-1250° C. at a rate of 7-5° C./hour;
(b) from 1250-1100° C. at a rate of 5-2° C./hour;
(c) from 1100-700° C. at a rate of 1.3-2.0° C./hour;
(d) from 700-400° C. at a rate of 3.5-7.0° C./hour;
(e) from 400-100° C. at a rate of 10-15° C./hour; and
(f) naturally to ambient temperature.

5. The process according to claim 1, wherein the crucible is arranged on the top of a movable plate and a rod is attached to the bottom of said plate; said rod having a water cooled rod inside.

6. The process according to claim 5, wherein during cooling there is a constant coaxial temperature drop of gradient 10-50° C./m with minimal or no radial temperature gradient.

7. The process according to claim 7, wherein the water-cooled rod is moved at a 0.8-1.4 the speed the crucible is moved.

8. The process according to claim 8, wherein the water-cooled rod is moved at the same speed as the crucible.

9. A calcium fluoride crystal suitable for use in optical communications elements, said crystal made by the process comprising:
(a) placing a calcium fluoride charge in a crucible;
(b) placing the crucible in a furnace having a melt zone and an annealing zone, said zones being separated by a diaphragm and each zone being heated independently by separate heaters;
(c) reducing the pressure in the furnace to not less than 1×10⁻⁶ mm Hg;
(d) heating the charge in the crucible to a temperature of 1500° C. and holding the charge in the melt zone at the temperature for a time sufficient for the charge to melt and the melt to become homogeneous and free of inclusions and bubbles;
(e) lowering the crucible containing the melt of step (d) from the melt zone into the annealing zone that is at a temperature of 1250° C. at a speed of 0.7-2.0 mm/hour until the crucible has passed the diaphragm; and
(f) lowering the temperature of the melt in a controlled manner to ambient temperature;
wherein said plate has a first rod attached to the bottom thereof and a second water-cooled rod located inside said first rod, the top of said water-cooled rod being disposed toward said crucible and being located at a distance 0.3-0.4 from the top of the overall height of the heater in the annealing zone; and
wherein when said crucible is moved from the melt zone into the annealing zone, the water-cooled rod is moved at a speed in the range of 0.8-1.4 the speed of the crucible.
